(19) United States
(12) Patent Application Publication
(10) Pub. No.: US 2007/0139079 A1
(43) Pub. Date: Jun. 21, 2007

(54) Reducing power noise in differential drivers

(76) Inventor: George C. Tang, Cupertino, CA (US)

Correspondence Address: Pete Scott, Senior Corporate Counsel;LSI Logic Corporation, Legal Department - IP, 1621 Barber Lane, MS D-106, Milpitas, CA, 95035, US

(21) Appl. No.: 11/314,855

(22) Filed: Dec. 20, 2005

(51) Int. Cl. H03K 19/094

(52) U.S. Cl. 326/87

(57) ABSTRACT

An improvement reducing or eliminating noise between drivers connected in common on a single chip. A DC power source (VDD1) providing a common signal to multiple PCML drivers and inductance introduced between a common DC power source and each of the multiple PCML drivers tied in common to the DC power source. The introduced inductance between VDD1 and each of the multiple PCML drivers reduces or eliminates AC noise from flowing between drivers and allows DC signaling to pass to all drivers commonly connected to VDD1.

### FIELD OF THE INVENTION

The present invention is generally related to signal drivers and receivers as used in the communications industry. More particularly, the present invention is related to a solution for reducing power noise in differential drivers such as PCML drivers.

### BACKGROUND

Drivers are used in communications. Because different circuits utilize different drivers for the transmitters and receivers, it is necessary to interface diverse driver types with varying loads. All drivers have different voltage swings and load end termination. Because there are so many types of communications drivers, there is a need for drivers that can interface with varying loads and avoid problems associated with noise, signal mismatch, delay, etc.

Delays are experienced whenever a single-ended signal, such as a CMOS signal output, is interfaced with a differential signal, such as an LVDS or PCML receiver loads. CMOS signal outputs are provided in the form of a single-ended outputs; but a differential signal load, such as an LVDS, has a differential input represented by two inputs, +Vin and −Vin. When a single ended signal (CMOS) must communicate with a differential signal, phase misalignment can be experienced.

Referring to FIG. 1, labeled as “prior art”, the PCML circuit 100 that is illustrated includes shows two PCML drivers connected to VDD1. Although only two drivers are shown in the FIG. 1, it is possible that over one hundred drivers can be found on a single chip. Each driver generates noise, which means that more drivers increase noise and the possibility of a data error. Noise from one driver can cause interference with subsequent drivers. Noise is created as drivers switch.

VDD1 is the DC power source that distributes power through a copper trace, also referred to as the power bus. The copper trace is usually a long and narrow strip of copper which has inductive and resistive properties. As an AC current is driven through the copper trace, a voltage drop is experience. Vn is noise voltage which is experience throughout the first driver. The second driver will get its power through VDD1 and the first driver, therefore the second driver will also experience noise introduced by switching noise created from the first driver.

What is needed is a redesign of the circuitry shown in FIG. 1 so that driver switching noise is no longer introduced through copper traces connected in common to VDD1 and other drivers.

### SUMMARY OF THE INVENTION

The following summary of the invention is provided to facilitate an understanding of some of the innovative features unique to the present invention and is not intended to be a full description. A full appreciation of the various aspects of the invention can be gained by taking the entire specification, claims, drawings and abstract as a whole.

It is therefore one aspect of the present invention to provide a solution for reducing power noise in differential drivers such as PCML drivers.

In accordance with features of the improvement reducing or eliminating noise between drivers connected in common on a single chip, a DC power source providing a common signal to multiple PCML drivers and inductance introduced between VDD1 and each of the multiple PCML drivers.

In accordance with the improvement, inductance introduced between VDD1 And each of the multiple PCML drivers reduces or eliminates AC noise from flowing between drivers and allows DC signaling to pass to all drivers commonly connected to VDD1.

### BRIEF DESCRIPTION OF THE DRAWINGS

The accompanying figures, in which like reference numerals refer to identical or functionally similar elements throughout the separate views and which are incorporated in and form part of the specification, further illustrate embodiments of the present invention.

FIG. 1 labeled as “prior art” illustrates a block diagram of a multiple driver chip arrangement wherein drivers are connected in common to a power bus.

FIG. 2 illustrates the preferred embodiment wherein inductance is introduced between VDD1 and each driver to reduce or eliminate AC noise and allow DC signaling to pass to all drivers commonly connected to VDD1.

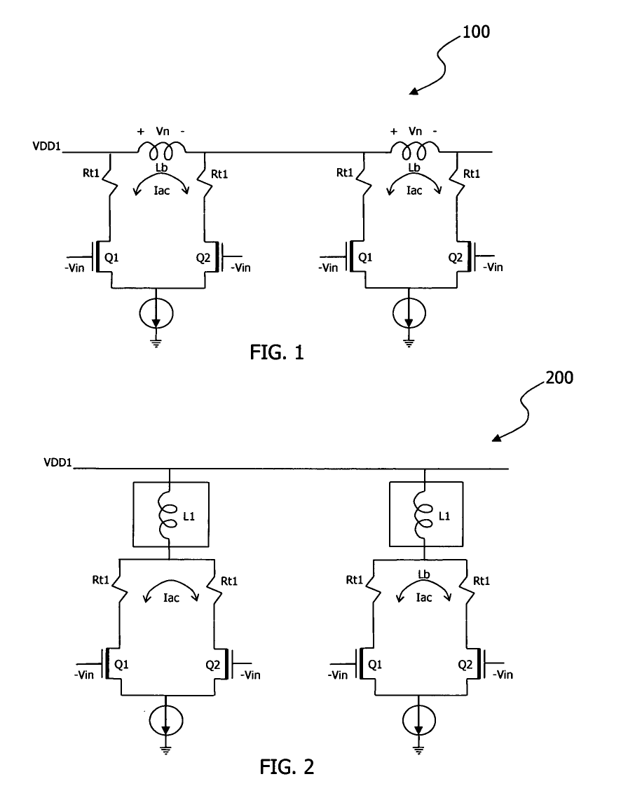

### DETAILED DESCRIPTION OF THE INVENTION

The particular values and configurations discussed in these non-limiting examples can be varied and are cited merely to illustrate embodiments of the present invention and are not intended to limit the scope of the invention.

As stated in the background, what is needed is a redesign of multiple driver circuitry shown in so that driver switching noise is no longer introduced through copper traces connected in common to VDD1 and other drivers arranged on a single chip.

Referring to FIG. 2, a block diagram of a simplified circuit 200 illustrates the improvement designed by the presented inventor to correct the influence of driver noise on subsequent drivers in a circuit. In accordance with the embodiment, a small inductance L1 is inserted between each driver and the power source VDD1. The added inductance L1 can be represented by the addition of a small copper trace introduced between VDD1 and the driver circuit.

During operation, when the transistors for each driver, Q1 and Q2, are switching within each driver, the overall summation of switching (AC) current is always the same because a constant DC current is flowing through L1. In other words the overall summation of current is the same during switching (i.e., when Q1 turns on and Q2 turns off, or when Q2 turns on and Q1 turns off). The AC current continues switching between the two transistors, but only DC current can flow through L1. This circuit design eliminates the power bus as a factor in signaling between drivers. Basically, AC noise is no longer transferable from one driver to the next with the introduction of L1.

The embodiments and examples set forth herein are presented to best explain the present invention and its practical application and to thereby enable those skilled in the art to make and utilize the invention. Those skilled in the art, however, will recognize that the foregoing description and examples have been presented for the purpose of illustration and example only. Other variations and modifications of the present invention will be apparent to those of skill in the art, and it is the intent of the appended claims that such variations and modifications be covered.

The description as set forth is not intended to be exhaustive or to limit the scope of the invention. Many modifications and variations are possible in light of the above teaching without departing from the scope of the following claims. It is contemplated that the use of the present invention can involve components having different characteristics. It is intended that the scope of the present invention be defined by the claims appended hereto, giving full cognizance to equivalents in all respects.

1. A driver circuit comprising inductance introduced between a DC power source providing a common signal to multiple drivers and each of the multiple drivers, wherein the introduced inductance between the DC power source and each of the multiple drivers reduces or eliminates AC noise from flowing between drivers and allows DC signaling to pass to all drivers commonly connected to the DC power source.

2. The driver circuit of claim 1 wherein said driver circuit reduces noise between drivers connected in common on a single chip.

3. The driver circuit of claim 1 wherein said multiple drivers are PCML drivers.

4. The driver circuit of claim 3 wherein said driver circuit reduces noise between drivers connected in common on a single chip.

5. The driver circuit of claim 2 wherein said multiple drivers are PCML drivers.

6. A driver circuit reducing or eliminating noise between drivers connected in common, comprising:
access to a DC power source providing a common signal to multiple PCML drivers; and
inductance introduced between the DC power source and each of the multiple PCML drivers;
wherein the introduced inductance between the DC power source and each of the multiple PCML drivers reduces or eliminates AC noise from flowing between drivers and allows DC signaling to pass to all drivers commonly connected to the DC power source.

7. The driver circuit of claim 6 wherein said driver circuit reduces noise between drivers connected in common on a single chip.

8. The driver circuit of claim 6 wherein said multiple drivers are PCML drivers.

9. The driver circuit of claim 8 wherein said driver circuit reduces noise between drivers connected in common on a single chip.

10. The driver circuit of claim 7 wherein said multiple drivers are PCML drivers.

11. A driver circuit reducing or eliminating noise between PCML drivers connected in common on a single chip, comprising:
a DC power source providing a common VDD1 signal to multiple PCML drivers; and
added inductance between VDD1 and each of the multiple PCML drivers;
wherein the added inductance between VDD1 and each of the multiple PCML drivers reduces or eliminates AC noise from flowing between drivers and allows DC signaling to pass to all drivers commonly connected to VDD1.
